(19) United States
(12) Patent Application Publication
(10) Pub. No.: US 2024/0283435 A1
(43) Pub. Date: Aug. 22, 2024

(54) Scan Flip Flop

(71) Applicant: Meta Platforms Technologies, LLC, Menlo Park, CA (US)

(72) Inventor: Saurabh Kumar, Portland, OR (US)

(21) Appl. No.: 18/171,074

(22) Filed: Feb. 17, 2023

(51) Int. Cl. H03K 3/037

(52) U.S. Cl. CPC H03K 3/0372; H03K 19/0002

(57) ABSTRACT

A scan flip-flop comprising a multiplexer configured to select from a plurality of inputs of the flip-flop. The scan flip-flop further comprises (1) a master latch configured to latch data selected by the multiplexer, wherein an input of the master latch is coupled to an output of the multiplexer, (2) a switch controlled by clock signals, wherein an input of the switch is coupled to an output of the master latch, and (3) a slave latch configured to latch data from the master latch. An input of the slave latch is coupled to an output of the switch, and the slave latch comprises a tri-state inverter controlled by clock signals. The tri-state inverter of the slave latch is configured to supply current to the multiplexer when the tri-state inverter is enabled by the clock signals.

### TECHNICAL FIELD

This disclosure generally relates to logic circuits and more specifically to scan flip flops.

### BACKGROUND

Flip-flops are digital circuit elements generally used for temporarily storing past input data. A flip-flop typically has two stable states and is designed to remember the last state until an input signal causes it to switch states.

A scan flip-flop is generally a flip-flop with a multiplexer (or mux) added to its input to select from a functional D input or a scan-in SI input. Selection between the two inputs is based on a Scan Enable (SE) signal. Scan flip-flops are commonly used to form scan chains. A series of scan flip-flops connected in a chain effectively form a shift register. Scan chains are commonly built into chips to provide a mechanism to test the functionality of the chip and to detect manufacturing faults.

### SUMMARY OF PARTICULAR EMBODIMENTS

Embodiments described herein pertain to an improved flip-flop, such as a scan flip-flop. In particular embodiments, a flip-flop comprises (1) a multiplexer configured to select from a plurality of inputs of the flip-flop; (2) a master latch configured to latch data selected by the multiplexer, wherein an input of the master latch is coupled to an output of the multiplexer; (3) a switch controlled by clock signals, wherein an input of the switch is coupled to an output of the master latch; and (4) a slave latch configured to latch data from the master latch. An input of the slave latch is coupled to an output of the switch, and the slave latch comprises a tri-state inverter controlled by clock signals. The tri-state inverter of the slave latch is configured to supply current to the multiplexer when the tri-state inverter is enabled by the clock signals.

In particular embodiments of the flip-flop, the multiplexer is enabled and disabled based on the current from the tri-state inverter. In particular embodiments, the tri-state inverter and the multiplexer are enabled when a clock signal is low, and the tri-state inverter and the multiplexer are disabled when a clock signal is high. In particular embodiments, the master latch comprises a second tri-state inverter that is enabled when a clock signal is high.

In particular embodiments of the flip-flop, a data path between the multiplexer and the master latch does not include a switch.

In particular embodiments of the flip-flop, the plurality of inputs of the flip-flop from which the multiplexer selects include a data input and a scan-in input.

In particular embodiments of the flip-flop, the master latch comprises a series of two inverters coupled to an input of a second tri-state inverter, wherein an output of the second tri-state inverter is coupled to an input of the series of two inverters. In particular embodiments, the slave latch further comprises a first inverter, wherein an output of the first inverter is coupled to an input of the tri-state inverter, and an output of the tri-state inverter is coupled to an input of the first inverter. In particular embodiments, an output of the flip-flop is generated by a second inverter, wherein an input of the second inverter is coupled to a node between the switch and the first inverter.

In particular embodiments of the flip-flop, a data path from the plurality of inputs of the flip-flop to an output of the flip-flop includes exactly five logic devices. In particular embodiments, the five logic devices consist of the multiplexer, the switch, and three inverters.

In particular embodiments of the flip-flop, the switch is a latch transmission gate.

In particular embodiments, a scan flip-flop comprises (1) a multiplexer configured to select from a plurality of inputs of the scan flip-flop, the plurality of inputs comprising a data input and a scan-in input; (2) a master latch configured to latch data selected by the multiplexer, wherein an input of the master latch is directly coupled to an output of the multiplexer; (3) a switch controlled by clock signals, wherein an input of the switch is coupled to an output of the master latch; and (4) a slave latch configured to latch data from the master latch, wherein an input of the slave latch is coupled to an output of the switch.

In particular embodiments of the scan flip-flop, the input of the master latch is directly coupled to the output of the multiplexer without a switch in between them.

In particular embodiments of the flip-flop, the slave latch further comprises a first inverter and a first tri-state inverter, wherein an output of the first inverter is coupled to an input of the first tri-state inverter, and an output of the first tri-state inverter is coupled to an input of the first inverter. In particular embodiments, the master latch comprises a series of two inverters coupled to an input of a second tri-state inverter, wherein an output of the second tri-state inverter is coupled to an input of the series of two inverters. In particular embodiments, an output of the flip-flop is generated by a second inverter, wherein an input of the second inverter is coupled to a node between the switch and the first inverter. In particular embodiments, the first tri-state inverter is configured to selectively enable and disable the multiplexer by selectively supplying current to the multiplexer. In particular embodiments, the first tri-state inverter selectively supplies current to the multiplexer according to clock signals.

Particular embodiments of a scan flip-flop comprise (1) a multiplexer configured to select from a plurality of inputs of the scan flip-flop, the plurality of inputs comprising a data input and a scan-in input; (2) a master latch configured to latch data selected by the multiplexer, wherein an input of the master latch is coupled to an output of the multiplexer; (3) a switch controlled by clock signals, wherein an input of the switch is coupled to an output of the master latch; and (4) a slave latch configured to latch data from the master latch, wherein an input of the slave latch is coupled to an output of the switch, and the slave latch comprises a tri-state inverter controlled by clock signals. A data path from the plurality of inputs of the flip-flop to an output of the flip-flop includes exactly five logic devices consisting of the multiplexer, the switch, and three inverters.

### BRIEF DESCRIPTION OF THE DRAWINGS

FIG. 1 illustrates a conventional scan flip-flop 100.

FIG. 2 illustrates an improved scan flip-flop 200, according to particular embodiments.

FIG. 3 illustrates an example computer system.

### DESCRIPTION OF EXAMPLE EMBODIMENTS

A scan flip-flop is one of the most common sequential cells used in logic design. Due to their prevalence use, optimization made to a scan flip-flop could have a big impact on a chip's overall power and performance.

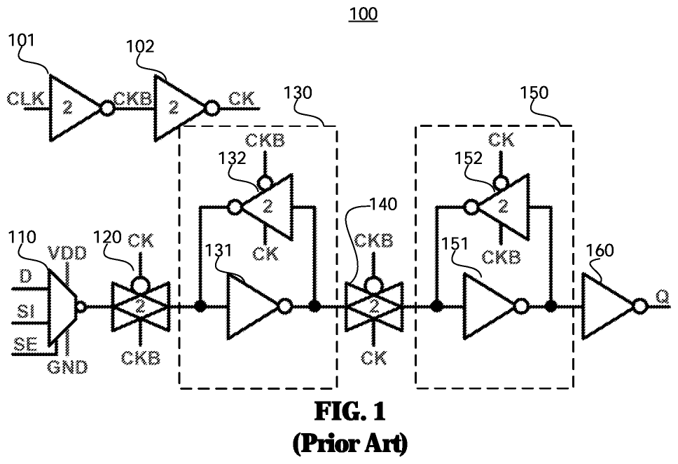

FIG. 1 illustrates a conventional scan flip-flop 100 implemented using a master latch 130 and a slave latch 150. The scan flip-flop 100 includes a mux 110 for selecting between the functional D input or scan-in SI input based on a scan enable SE signal. Operational power is supplied to mux 110 via voltage VDD and ground GND pins. The output of the mux 110 is an inversion of the selected input (i.e., the output is either an inverted D or inverted SI).

A first latch transmission gate 120, which functions like a switch, is placed between the output of the mux 110 and the input of the master latch 130. The latch transmission gate 120 has two inputs—the clock signal CK and its inverse clock signal CKB (Clock-Bar). Both are generated from the system clock signal CLK. As shown in FIG. 1, CLK is inverted by inverter 101 to generate CKB, and CKB is again inverted by inverter 102 to generate CK. When CK is low or 0, the latch transmission gate 120 would allow the output of mux 110 to pass to the master latch 130; when CK is high or 1, the latch transmission gate 120 would block the data path.

The master latch 130 comprises an inverter 131 and a tri-state inverter 132 arranged in a closed loop. The inverter 131 receives the input signal, inverts it, and passes the output to the tri-state inverter 132. The tri-state inverter 132 is enabled or disabled based on clock signals. This particular tri-state inverter 132 is enabled when the clock signal CK is high or 1 and disabled when the CK is low or 0. When enabled, the tri-state inverter 132 would invert its input; when disabled, the tri-state inverter 132 would output a third Z state, which is functionally equivalent to no output. The output of the tri-state inverter 132 is coupled to the input of the inverter 131, thereby forming a loop.

The output of the master latch 130 is coupled to a second latch transmission gate 140. When CK is high or 1, the latch transmission gate 130 would allow the output of the master latch 130 to pass to the slave latch 150; when CK is low or 0, the latch transmission gate 140 would block the data path.

The slave latch 150 comprises an inverter 151 and a tri-state inverter 152 arranged in a closed loop. The inverter 151 is configured to receive the input signal from the master latch 130, invert it, and pass the output to the tri-state inverter 152. The tri-state inverter 152 is enabled or disabled based on clock signals. This particular tri-state inverter 152 is enabled when the clock signal CK is low or 0 and disabled when the CK is high or 1. When enabled, the tri-state inverter 152 would invert its input; when disabled, the tri-state inverter 152 would output a third Z state, which is functionally equivalent to no output. The output of the tri-state inverter 152 is coupled to the input of the inverter 151, thereby forming a loop. Finally, the output of the slave latch 150 is passed to a final inverter 160 before being outputted as Q, the output of the scan flip-flop 100.

Several features of the conventional scan flip-flop 100 are worth noting. In scan flip-flop 100, mux 110 is powered via VDD/GND. This means that mux 110 is always on when the circuit is on, which in turn means higher power leakage. This scan flip-flop 100 also has twelve clock fan-out devices: two for inventor 101, two for inventor 102, two for latch transmission gate 120, two for tri-state inverter 132, two for latch transmission gate 140, and two for tri-state inverter 152. Having more clock fan-out devices results in more dynamic power consumption. Lastly, the data path from the input D/SI to the output Q includes six logic devices: mux 110, latch transmission gate 120, inverter 131, latch transmission gate 140, inverter 151, and inverter 160. Since each device in the data path causes some amount of latency to the signal, the more devices in a data path, the more resulting aggregate latency.

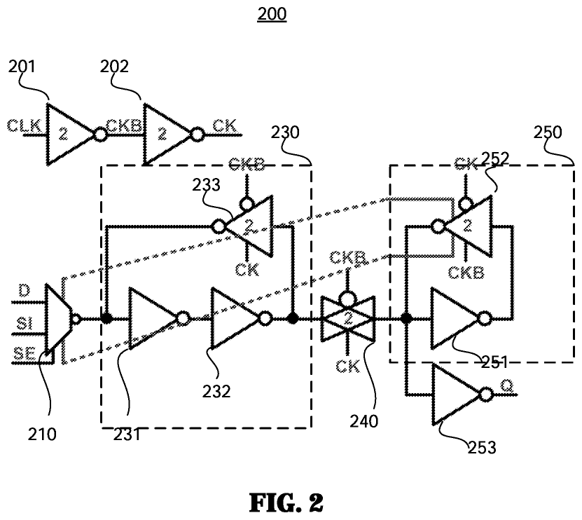

FIG. 2 illustrates an improved scan flip-flop 200 with lower-power consumption and higher performance. Scan flip-flop 200 has a master latch 230 and a slave latch 250 operated by two clock signals, CKB and CK. Both clock signals are generated from the system clock CLK. A first inverter 201 inverts the system clock signal CLK to generate CKB, and another inverter 202 inverts CKB to generate CK.

Scan flip-flop 200 has a mux 210 for selecting either functional data input D or scan-in SI based on a scan enable SE signal. The output of mux 210 is an inversion of the selected input. In particular embodiments, the output of mux 210 is directly provided to master latch 230. This design is different from the conventional scan flip-flop 100, which uses a latch transmission gate 120 to allow or block the output of mux 110 from reaching master latch 130. Scan flip-flop 200 achieves a similar switching functionality through a different means. In contrast to the mux 110 of conventional scan flip-flop 100, mux 210 does not receive current from a direct VDD/GND connection. Instead, mux 210 receives current from tri-state inverter 252 of slave latch 250. Tri-state inverter 252 is enabled when CK is low or 0 and disabled when CK is high or 1. Thus, mux 210 would receive current from tri-state inverter 252 and become operational when CK is low or 0. When CK is high or 1, tri-state inverter 252 would not supply current to mux 210, thereby disabling the mux 210.

There are several advantages to this design of scan flip flop 200. In the conventional design, mux 110 is connected to VDD/GND, which means power is leaking 100% of the time when the system is on. In contrast, mux 210 of scan flip flop 200 would only receive current when tri-state inverter 252 is enabled. Specifically, mux 210 would receive current when CK is low and would not receive current when CK is high. If CK is low 50% of the time, mux 210 would save 50% of the power. Thus, mux 210's power footprint is much lower than that of mux 110 in the conventional design.

Another benefit of the current design is that no latch transmission gate is used to allow or block input to the master latch 230. The conventional scan flip flop 100 uses two latch transmission gates 120, 140, whereas the current scan flip flop 200 uses only one 240. As previously discussed, scan flip-flop 100 has twelve clock fan-out devices: two for inventor 101, two for inventor 102, two for latch transmission gate 120, two for tri-state inverter 132, two for latch transmission gate 140, and two for tri-state inverter 152. In contrast, the present scan flip-flop 200 has ten clock fan-out devices: two for inventor 201, two for inventor 202, two for tri-state inverter 233, two for latch transmission gate 240, and two for tri-state inverter 252. Since the current scan flip flop 200 has only ten clock fan-out devices compared to twelve such devices in the conventional flip flop 100, the current scan flip flop 200 uses less dynamic power and has less leakage.

Performance is yet another benefit of the present scan flip flop 200. As shown in FIG. 2, the output of mux 210 is connected to the input of master latch 230. Within master latch 230, the input is connected to a series of two inverters 231 and 232. The output of the second inverter 232 is connected to the input of tri-state inverter 233. The output of tri-state inverter 233 is then looped back to the input of inverter 231. The output of master latch 230 is connected to latch transmission gate 240, which may be enabled when CK is high. The output of latch transmission gate 240 is connected to the input of slave latch 250. The input to slave latch 250 is coupled to inverter 251, which in turn sends data to tri-state inverter 252. The output of tri-state inverter 252 then loops back to inverter 251. The output of slave latch 250 is provided to inverter 253, which outputs Q, the final output of the scan flip-flop 200.

One benefit of the circuit of scan flip-flop 200 is that the input-to-output data path has less latency. As shown in FIG. 2, the signal entering scan flip-flop 200 would pass through five logic devices: mux 210, inverter 231, inverter 232, latch transmission gate 240, and inverter 253. As a point of comparison, in the conventional scan flip-flop 100 shown in FIG. 1, the input-to-output data path has six logic devices: mux 110, latch transmission gate 120, inverter 131, latch transmission gate 140, inverter 151, and inverter 160. Since the input-to-output data path of the current scan flip-flop 200 has fewer logic devices, it would have less latency caused by those devices.

Another performance improvement of scan flip-flop 200 is achieved by reconfiguring the inverters. Compared to the master latch 130 of the convention scan flip-flop 100 shown in FIG. 1, the master latch 230 of the present scan flip-flop 200 has an extra inverter 232 placed after inverter 231. In addition, the final inverter 253 that outputs Q is configured to invert the input of slave latch 250 rather than the output of inverter 251. The change in inverter configuration would not alter the functionality of scan flip-flop 200. In order for the input D/SI of scan flip-flop 200 to be its output Q, the input-to-output data path would need to include an even number of inverters. For example, in scan flip-flop 200, the input-to-output data path has four inverters: inventor of mux 210, inverter 231, inverter 232, and inverter 253. Another configuration constraint is that the value latched by the mater latch 230 and the value latched by the slave latch 250 need to be inverses of each other. This is also achieved in this circuit 200 because the output of inverter 232, which is latched by master latch 230, is inverted by inverter 251 of the slave latch 250 before the value is latched. This new configuration improves performance because the number of logic devices between latch transmission gate 240 and Q is reduced compared to the conventional technique. In the conventional scan flip-flop 100, there are two inverters 151, 160 after latch transmission gate 140, whereas the present scan flip-flop 200 has only one inverter 253. This means that after the latch transmission gate 240 is enabled, the signal only needs to pass through one inverter 253 instead of two. As such, the circuit design of the present scan flip-flop can achieve improved latency performance.

Through experimentation, it has been demonstrated that the present scan flip-flop 200 outperforms the conventional scan flip-flop 100. For example, the average total power improvement is 10.96%; the average leakage improvement is 3.4%, the average performance improvement is 16.84%, and the average area improvement is 3.4%.

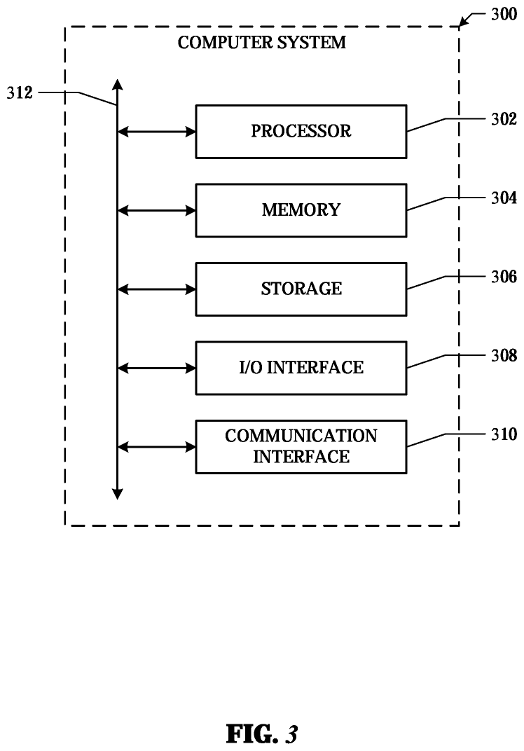

FIG. 3 illustrates an example computer system 300 that may employ the scan flip-flop described herein. FIG. 3 illustrates an example computer system 300. In particular embodiments, one or more computer systems 300 perform one or more steps of one or more methods described or illustrated herein. In particular embodiments, one or more computer systems 300 provide functionality described or illustrated herein. In particular embodiments, software running on one or more computer systems 300 performs one or more steps of one or more methods described or illustrated herein or provides functionality described or illustrated herein. Particular embodiments include one or more portions of one or more computer systems 300. Herein, reference to a computer system may encompass a computing device, and vice versa, where appropriate. Moreover, reference to a computer system may encompass one or more computer systems, where appropriate.

This disclosure contemplates any suitable number of computer systems 300. This disclosure contemplates computer system 300 taking any suitable physical form. As example and not by way of limitation, computer system 300 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, an augmented/virtual reality device, or a combination of two or more of these. Where appropriate, computer system 300 may include one or more computer systems 300; be unitary or distributed; span multiple locations; span multiple machines; span multiple data centers; or reside in a cloud, which may include one or more cloud components in one or more networks. Where appropriate, one or more computer systems 300 may perform without substantial spatial or temporal limitation one or more steps of one or more methods described or illustrated herein. As an example and not by way of limitation, one or more computer systems 300 may perform in real time or in batch mode one or more steps of one or more methods described or illustrated herein. One or more computer systems 300 may perform at different times or at different locations one or more steps of one or more methods described or illustrated herein, where appropriate.

In particular embodiments, computer system 300 includes a processor 302, memory 304, storage 306, an input/output (I/O) interface 308, a communication interface 310, and a bus 312. Although this disclosure describes and illustrates a particular computer system having a particular number of particular components in a particular arrangement, this disclosure contemplates any suitable computer system having any suitable number of any suitable components in any suitable arrangement.

In particular embodiments, processor 302 includes hardware for executing instructions, such as those making up a computer program. As an example and not by way of limitation, to execute instructions, processor 302 may retrieve (or fetch) the instructions from an internal register, an internal cache, memory 304, or storage 306; decode and execute them; and then write one or more results to an internal register, an internal cache, memory 304, or storage 306. In particular embodiments, processor 302 may include one or more internal caches for data, instructions, or addresses. This disclosure contemplates processor 302 including any suitable number of any suitable internal caches, where appropriate. As an example and not by way of limitation, processor 302 may include one or more instruction caches, one or more data caches, and one or more translation lookaside buffers (TLBs). Instructions in the instruction caches may be copies of instructions in memory 304 or storage 306, and the instruction caches may speed up retrieval of those instructions by processor 302. Data in the data caches may be copies of data in memory 304 or storage 306 for instructions executing at processor 302 to operate on; the results of previous instructions executed at processor 302 for access by subsequent instructions executing at processor 302 or for writing to memory 304 or storage 306; or other suitable data. The data caches may speed up read or write operations by processor 302. The TLBs may speed up virtual-address translation for processor 302. In particular embodiments, processor 302 may include one or more internal registers for data, instructions, or addresses. This disclosure contemplates processor 302 including any suitable number of any suitable internal registers, where appropriate. Where appropriate, processor 302 may include one or more arithmetic logic units (ALUs); be a multi-core processor; or include one or more processors 302. Although this disclosure describes and illustrates a particular processor, this disclosure contemplates any suitable processor.

In particular embodiments, memory 304 includes main memory for storing instructions for processor 302 to execute or data for processor 302 to operate on. As an example and not by way of limitation, computer system 300 may load instructions from storage 306 or another source (such as, for example, another computer system 300) to memory 304. Processor 302 may then load the instructions from memory 304 to an internal register or internal cache. To execute the instructions, processor 302 may retrieve the instructions from the internal register or internal cache and decode them. During or after execution of the instructions, processor 302 may write one or more results (which may be intermediate or final results) to the internal register or internal cache. Processor 302 may then write one or more of those results to memory 304. In particular embodiments, processor 302 executes only instructions in one or more internal registers or internal caches or in memory 304 (as opposed to storage 306 or elsewhere) and operates only on data in one or more internal registers or internal caches or in memory 304 (as opposed to storage 306 or elsewhere). One or more memory buses (which may each include an address bus and a data bus) may couple processor 302 to memory 304. Bus 312 may include one or more memory buses, as described below. In particular embodiments, one or more memory management units (MMUs) reside between processor 302 and memory 304 and facilitate accesses to memory 304 requested by processor 302. In particular embodiments, memory 304 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 304 may include one or more memories 304, where appropriate. Although this disclosure describes and illustrates particular memory, this disclosure contemplates any suitable memory.

In particular embodiments, storage 306 includes mass storage for data or instructions. As an example and not by way of limitation, storage 306 may include a hard disk drive (HDD), a floppy disk drive, flash memory, an optical disc, a magneto-optical disc, magnetic tape, or a Universal Serial Bus (USB) drive or a combination of two or more of these. Storage 306 may include removable or non-removable (or fixed) media, where appropriate. Storage 306 may be internal or external to computer system 300, where appropriate. In particular embodiments, storage 306 is non-volatile, solid-state memory. In particular embodiments, storage 306 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 306 taking any suitable physical form. Storage 306 may include one or more storage control units facilitating communication between processor 302 and storage 306, where appropriate. Where appropriate, storage 306 may include one or more storages 306. Although this disclosure describes and illustrates particular storage, this disclosure contemplates any suitable storage.

In particular embodiments, I/O interface 308 includes hardware, software, or both, providing one or more interfaces for communication between computer system 300 and one or more I/O devices. Computer system 300 may include one or more of these I/O devices, where appropriate. One or more of these I/O devices may enable communication between a person and computer system 300. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 308 for them. Where appropriate, I/O interface 308 may include one or more device or software drivers enabling processor 302 to drive one or more of these I/O devices. I/O interface 308 may include one or more I/O interfaces 308, where appropriate. Although this disclosure describes and illustrates a particular I/O interface, this disclosure contemplates any suitable I/O interface.

In particular embodiments, communication interface 310 includes hardware, software, or both providing one or more interfaces for communication (such as, for example, packet-based communication) between computer system 300 and one or more other computer systems 300 or one or more networks. As an example and not by way of limitation, communication interface 310 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 310 for it. As an example and not by way of limitation, computer system 300 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 300 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. Computer system 300 may include any suitable communication interface 310 for any of these networks, where appropriate. Communication interface 310 may include one or more communication interfaces 310, where appropriate. Although this disclosure describes and illustrates a particular communication interface, this disclosure contemplates any suitable communication interface.

In particular embodiments, bus 312 includes hardware, software, or both coupling components of computer system 300 to each other. As an example and not by way of limitation, bus 312 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 312 may include one or more buses 312, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

What is claimed is:

1. A flip-flop, comprising:
a multiplexer configured to select from a plurality of inputs of the flip-flop;
a master latch configured to latch data selected by the multiplexer, wherein an input of the master latch is coupled to an output of the multiplexer;
a switch controlled by clock signals, wherein an input of the switch is coupled to an output of the master latch; and
a slave latch configured to latch data from the master latch, wherein an input of the slave latch is coupled to an output of the switch, and the slave latch comprises a tri-state inverter controlled by clock signals;
wherein the tri-state inverter of the slave latch is configured to supply current to the multiplexer when the tri-state inverter is enabled by the clock signals.

2. The flip-flop of claim 1, wherein the multiplexer is enabled and disabled based on the current from the tri-state inverter.

3. The flip-flop of claim 2, wherein the tri-state inverter and the multiplexer are enabled when a clock signal is low, and the tri-state inverter and the multiplexer are disabled when a clock signal is high.

4. The flip-flop of claim 3, wherein the master latch comprises a second tri-state inverter that is enabled when a clock signal is high.

5. The flip-flop of claim 1, wherein a data path between the multiplexer and the master latch does not include a switch.

6. The flip-flop of claim 1, wherein the plurality of inputs of the flip-flop from which the multiplexer selects include a data input and a scan-in input.

7. The flip-flop of claim 1, wherein the master latch comprises a series of two inverters coupled to an input of a second tri-state inverter, wherein an output of the second tri-state inverter is coupled to an input of the series of two inverters.

8. The flip-flop of claim 7, wherein the slave latch further comprises a first inverter, wherein an output of the first inverter is coupled to an input of the tri-state inverter, and an output of the tri-state inverter is coupled to an input of the first inverter.

9. The flip-flop of claim 8, wherein an output of the flip-flop is generated by a second inverter, wherein an input of the second inverter is coupled to a node between the switch and the first inverter.

10. The flip-flop of claim 1, wherein a data path from the plurality of inputs of the flip-flop to an output of the flip-flop includes exactly five logic devices.

11. The flip-flop of claim 10, wherein the five logic devices consist of the multiplexer, the switch, and three inverters.

12. The flip-flop of claim 1, wherein the switch is a latch transmission gate.

13. A scan flip-flop, comprising:
a multiplexer configured to select from a plurality of inputs of the scan flip-flop, the plurality of inputs comprising a data input and a scan-in input;
a master latch configured to latch data selected by the multiplexer, wherein an input of the master latch is directly coupled to an output of the multiplexer;
a switch controlled by clock signals, wherein an input of the switch is coupled to an output of the master latch; and
a slave latch configured to latch data from the master latch, wherein an input of the slave latch is coupled to an output of the switch.

14. The scan flip-flop of claim 13, wherein the input of the master latch is directly coupled to the output of the multiplexer without a switch in between them.

15. The scan flip-flop of claim 13, wherein the slave latch further comprises a first inverter and a first tri-state inverter, wherein an output of the first inverter is coupled to an input of the first tri-state inverter, and an output of the first tri-state inverter is coupled to an input of the first inverter.

16. The scan flip-flop of claim 15, wherein the master latch comprises a series of two inverters coupled to an input of a second tri-state inverter, wherein an output of the second tri-state inverter is coupled to an input of the series of two inverters.

17. The scan flip-flop of claim 16, wherein an output of the flip-flop is generated by a second inverter, wherein an input of the second inverter is coupled to a node between the switch and the first inverter.

18. The scan flip-flop of claim 15, wherein the first tri-state inverter is configured to selectively enable and disable the multiplexer by selectively supplying current to the multiplexer.

19. The scan flip-flop of claim 18, wherein the first tri-state inverter selectively supplies current to the multiplexer according to clock signals.

20. A scan flip-flop, comprising:
a multiplexer configured to select from a plurality of inputs of the scan flip-flop, the plurality of inputs comprising a data input and a scan-in input;
a master latch configured to latch data selected by the multiplexer, wherein an input of the master latch is coupled to an output of the multiplexer;
a switch controlled by clock signals, wherein an input of the switch is coupled to an output of the master latch; and
a slave latch configured to latch data from the master latch, wherein an input of the slave latch is coupled to an output of the switch, and the slave latch comprises a tri-state inverter controlled by clock signals;
wherein a data path from the plurality of inputs of the flip-flop to an output of the flip-flop includes exactly five logic devices consisting of the multiplexer, the switch, and three inverters.
